(19) United States
(12) Patent Application Publication
(10) Pub. No.: US 2026/0088690 A1
(43) Pub. Date: Mar. 26, 2026

(54) ELECTRICAL ENERGY PRODUCED BY ROTATING MAGNETS

(71) Applicant: Tokyo Electron Limited, Tokyo (JP)

(72) Inventors: Mark I. GARDNER, Austin, TX (US); H. Jim FULFORD, Marianna, FL (US); Daniel FULFORD, Albany, NY (US)

(73) Assignee: Tokyo Electron Limited, Tokyo (JP)

(21) Appl. No.: 18/893,492

(22) Filed: Sep. 23, 2024

(51) Int. Cl. H02K 21/24; B05D 1/00; G03F 7/16

(52) U.S. Cl. CPC H02K 21/24; B05D 1/005; G03F 7/162

(57) ABSTRACT

A substrate processing apparatus includes a substrate holder configured to receive a substrate, a shaft connected to the substrate holder at one end of the shaft and configured to rotate the substrate holder, a plate attached to the shaft and configured to rotate with the shaft, magnets integrated with the substrate holder, the plate or both, and a coiled wire positioned between the substrate holder and the plate and configured to generate an electrical current when the shaft rotates. A method of energy generation includes providing the substrate processing apparatus and rotating the shaft to generate the electrical current.

### FIELD OF THE INVENTION

This disclosure relates generally to energy production and more specifically to electrical energy induced by a changing magnetic field. This disclosure also relates to a substrate processing apparatus.

### BACKGROUND

Faraday's law of induction, also known as Faraday's law, is a law of electromagnetism predicting how a magnetic field will interact with an electric circuit to produce an electromotive force. That is, a changing magnetic field induces a voltage in a circuit. This phenomenon known as electromagnetic induction is the fundamental operating principle of transformers, inductors, electric motors, generators, solenoids, etc. Maxwell's equations include four equations that together form a description of the production and interrelation of electric and magnetic fields.

One of the four equations, the Maxwell-Faraday equation describes the fact that electric fields are produced by changing magnetic fields. Particularly, there is an electromotive force on a conductive loop when the magnetic flux through the surface enclosed by the loop varies in time.

### SUMMARY

The present disclosure relates to a substrate processing apparatus and a method of energy generation.

According to a first aspect of the disclosure, a substrate processing apparatus is provided. The substrate processing apparatus includes a substrate holder configured to receive a substrate, a shaft connected to the substrate holder at one end of the shaft and configured to rotate the substrate holder, a plate attached to the shaft and configured to rotate with the shaft, magnets integrated with the substrate holder, the plate or both, and a coiled wire positioned between the substrate holder and the plate and configured to generate an electrical current when the shaft rotates.

In some embodiments, the magnets include bar magnets arranged along a direction of a circumference of the shaft.

In some embodiments, the bar magnets each have a respective magnetic pole pointing towards the shaft.

In some embodiments, the bar magnets have alternating magnetic polarity along the direction of the circumference of the shaft.

In some embodiments, the magnets include an even number of the bar magnets.

In some embodiments, the bar magnets are configured to rotate around the shaft when the shaft rotates.

In some embodiments, the magnets are embedded in the plate.

In some embodiments, the magnets are embedded in the substrate holder.

In some embodiments, the magnets are embedded in the plate and the substrate holder.

In some embodiments, the coiled wire is configured to be stationary when the shaft rotates.

In some embodiments, the substrate processing apparatus further includes a conductor wire around which the coiled wire coils.

In some embodiments, the substrate processing apparatus further includes a battery connected to the conductor wire and configured to receive and store the electrical current.

In some embodiments, the shaft extends through the plate. The plate is below the coiled wire, and the coiled wire is below the substrate holder.

In some embodiments, the substrate processing apparatus includes a plurality of coiled wires arranged along a direction of a circumference of the shaft.

In some embodiments, the substrate processing apparatus further includes a nozzle configured to discharge a liquid onto the substrate.

According to a second aspect of the disclosure, a method of energy generation is provided. The method includes providing a substrate processing apparatus that includes a substrate holder configured to receive a substrate, a shaft connected to the substrate holder at one end of the shaft and configured to rotate the substrate holder, a plate attached to the shaft and configured to rotate with the shaft, magnets integrated with the substrate holder, the plate or both, and a coiled wire positioned between the substrate holder and the plate and configured to generate an electrical current when the shaft rotates. The method also includes rotating the shaft to generate the electrical current.

In some embodiments, the electrical current is transferred to a battery via a conductor wire around which the coiled wire coils.

In some embodiments, the coiled wire is kept stationary when rotating the shaft.

In some embodiments, the substrate processing apparatus includes a spin coater.

In some embodiments, a thin film is formed on the substrate by spin coating.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1A shows a vertical cross-sectional view of a substrate processing apparatus in accordance with some embodiments of the present disclosure.

FIGS. 1B and 1C show horizontal cross-sectional views of components of the substrate processing apparatus in accordance with some embodiments of the present disclosure.

FIG. 2A shows a vertical cross-sectional view of a substrate processing apparatus in accordance with some embodiments of the present disclosure.

FIGS. 2B and 2C show horizontal cross-sectional views of components of the substrate processing apparatus in accordance with some embodiments of the present disclosure.

FIG. 3A shows a vertical cross-sectional view of a substrate processing apparatus in accordance with some embodiments of the present disclosure.

FIGS. 3B and 3C show horizontal cross-sectional views of components of the substrate processing apparatus in accordance with some embodiments of the present disclosure.

FIG. 4A shows a horizontal cross-sectional view of components of the substrate processing apparatus in accordance with some embodiments of the present disclosure.

FIG. 4B shows an expanded local view of the substrate processing apparatus in accordance with some embodiments of the present disclosure.

FIG. 5 shows a flow chart of a process for manufacturing a semiconductor device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

A numerical range represented by “to” includes numerical values at both ends, unless specified otherwise.

In semiconductor manufacturing, a substrate processing apparatus often includes a rotating shaft to rotate a component of the substrate processing apparatus such as a wafer chuck or a wafer stage. Therefore, a wafer or substrate can be rotated for example during spin coating, vapor-phase film deposition, plasma etching, etc. to ensure uniformity. However, the rotational energy is otherwise not utilized.

Techniques herein utilize the rotational energy, when a wafer is rotated, to generate an electrical energy. According to the aforementioned Faraday's law of induction and aspects of the present disclosure, a changing magnetic field can induce an electrical current in an adjacent coiled wire next to the varying magnetic field for semiconductor rotating wafer chuck tool applications. Techniques herein can utilize an existing semiconductor tool or a new semiconductor tool design that rotates a wafer during wafer processing while adding additional features to the chuck region of the tool such that an electrical energy may be derived from a rotational energy produced by a wafer chuck and/or a shaft stage using rotating magnets. As a result, free electrical energy can be produced from a tool that already uses a rotating chuck in the tool design, which reduces electron energy consumption and carbon footprint. The extra electrical energy obtained is important to entities that are required to produce more energy-efficient semiconductor tools. The additional electrical energy generated may be stored in a battery or used to augment tool energy requirements. Many state-of-the-art tools currently have rotating chucks such as photoresist coating systems, wafer spin dryers, wafer cleaning tools, wafer deposition tools, etc. but do not generate electrical energy with the traditional rotating chuck design. Techniques herein will provide for this energy generation feature.

According to aspects of the present disclosure, a substrate processing apparatus can include a rotating chuck with magnets rotating relative to fixed coiled wire that is adjacent to the wafer chuck. Alternatively or additionally, the substrate processing apparatus can include a rotating chuck base platform with magnets attached and rotated on the base platform. Techniques herein can provide electrical current energy from both rotating and non-rotating chucks as options. Since the base platform is already rotating, a novel chuck design is enabled.

In a first embodiment, the substrate processing apparatus includes a rotating stage, fixed magnets attached to the rotating stage, and a fixed concentric wire wrapped around an adjacent conductor to capture the electrical current generated by the 1 changing magnetic field. This electrical current may then be stored in a battery or used in other regions of the tool to reduce tool power consumption. That is, a changing magnetic field can be created by rotating fixed magnets integrated on a horizontal mounted rotating wafer stage, so the changing magnetic field will induce an electrical current in an adjacent wire coiled along a conductor wire, and then this conductor wire is connected to a battery as one example.

In a second embodiment, the substrate processing apparatus includes a rotating stage, fixed magnets attached to only chuck regions, and a fixed concentric wire wrapped around an adjacent conductor to capture the electrical current by the 1 changing magnetic field locations. This electrical current may then be stored in a battery or used in other regions of the tool to reduce tool power consumption. That is, a changing magnetic field can be created by rotating fixed magnets integrated on a horizontal mounted rotating wafer chuck, so the changing magnetic field will induce an electrical current in an adjacent wire coiled along a conductor wire, and then this conductor wire is connected to a battery as one example.

In a third embodiment, the substrate processing apparatus includes a rotating stage, fixed magnets attached to both the stage and chuck regions, and a fixed concentric wire wrapped around an adjacent conductor to capture the electrical current by the 2 changing magnetic fields. This electrical current may then be stored in a battery or used in other regions of the tool to reduce tool power consumption. That is, a changing magnetic field can be created by rotating fixed magnets integrated on both a horizontal mounted rotating wafer stage and a horizontal mounted rotating wafer chuck, so the changing magnetic field will induce an electrical current in an adjacent wire coiled along a conductor wire, and then this conductor wire is connected to a battery as one example.

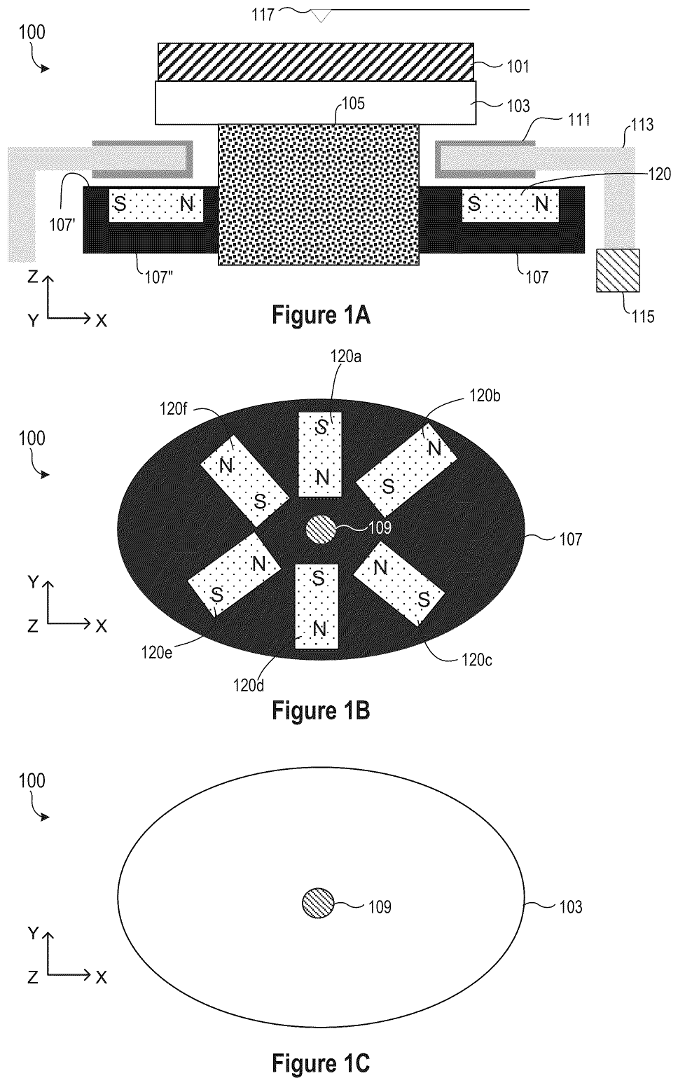

FIG. 1A shows a vertical cross-sectional view of a substrate processing apparatus (hereinafter referred to as an apparatus 100), in accordance with some embodiments of the present disclosure. The apparatus 100 includes a substrate holder 103 that is configured to receive a substrate 101. A shaft 105 (also referred to as a rod) is connected to the substrate holder 103 at one end of the shaft 105 and configured to rotate the substrate holder 103. A plate 107 (also referred to as a wafer stage or a rotating stage) is attached to the shaft 105 and configured to rotate with the shaft 105 when the shaft 105 rotates. Magnets 120 can be integrated with the plate 107. A coiled wire 111 can be positioned between the substrate holder 103 and the plate 107 and configured to generate an electrical current when the shaft 105 rotates.

In some embodiments, the magnets 120 are integrated with the plate 107 so that the magnets 120 are part of the plate 107. For instance, the magnets 120 can be embedded in the plate 107. As a result, the magnets 120 are configured to rotate with the plate 107 when the shaft 105 rotates. The position of the magnets 120 in the vertical direction (i.e. the Z direction) is not particularly limited. Preferably, the magnets 120 are closer to a top surface 107′ of the plate 107 than a bottom surface 107′ of the plate 107. The magnets 120 may preferably be covered by the top surface 107′ of the plate 107 or alternatively be exposed.

In some embodiments, the apparatus 100 includes a spin coater that is used to form a photoresist layer, a spin-on carbon film, etc. on the substrate 101. Accordingly, the apparatus 100 includes a nozzle 117 that is configured to discharge a liquid onto the substrate 101. During the operation of spin coating, the shaft 105 rotates so that the substrate holder 103 and the plate 107 also rotate. At the same time, the coiled wire 111 can be kept stationary. Therefore, an electrical current is generated by the coiled wire 111 due to changing magnetic fields of the magnets 120 that are rotating. A liquid (e.g. a photoresist solution, a polymer solution, a spin-on carbon solution, etc.) can be discharged onto the substrate 101 by the nozzle 117, when the shaft 105 is rotating, to form a thin film on the substrate 101. Alternatively or additionally, the apparatus 100 can include a wafer spin dryer, a wafer cleaning tool, a vapor-phase film deposition tool and the like, which also require rotation of the substrate 101 and thus rotation of the shaft 105 and the magnets 120. Similarly, an electrical current can be generated by the coiled wire 111.

FIGS. 1B and 1C show horizontal cross-sectional views of the plate 107 and the substrate holder 103 respectively. An insert opening 109 extends through both the plate 107 and the substrate holder 103. The shaft 105 is inserted in the insert opening 109. Note that the drawings in the present disclosure are merely for illustrative purposes and are not drawn to scale.

In some embodiments, the magnets 120 can include bar magnets 120a, 120b, 120c, 120d, 120e and 120f that are arranged along a direction of a circumference of the shaft 105 (or the insert opening 109). Each of the bar magnets 120a-120f has a respective magnetic pole pointing towards the shaft 105 and another respective magnetic pole pointing away from the shaft 105. In other words, the bar magnets 120a-120f each have a respective longitudinal direction that passes or is aligned to point towards the shaft 105. Preferably, the bar magnets 120a-120f are distributed uniformly along the direction of the circumference of the shaft 105; that is, the bar magnets 120a-120f may each form a 60-degree angle with a neighboring bar magnet. Alternatively, the bar magnets 120a-120f may be distributed non-uniformly along the direction of the circumference of the shaft 105.

The bar magnets 120a-120f can have alternating or reversed magnetic polarity along the direction of the circumference of the shaft 105. Consider the bar magnet 120c for example. The bar magnet 120c has a magnetic north pole pointing towards the shaft 105 while neighboring bar magnets (120b and 120d) each have a respective magnetic south pole pointing towards the shaft 105 in the example of FIG. 1B. In an alternative example, the bar magnet 120c can have a magnetic south pole pointing towards the shaft 105 while neighboring bar magnets (120b and 120d) each have a respective magnetic north pole pointing towards the shaft 105. Accordingly, the apparatus 100 may preferably include an even number (e.g. two, four, six, eight, etc.) of bar magnets.

The magnets 120 can each include a permanent magnet such as a natural magnet (e.g. magnetite) and an artificial magnet (e.g. alnico). Examples of the permanent magnet include, but are not limited to, an aluminum-nickel-cobalt magnet, a strontium-iron magnet (ferrite and ceramics), a neodymium-iron-boron magnet (neodymium magnets) and a samarium-cobalt magnet.

The coiled wire 111 can be positioned adjacent to the plate 107 or adjacent to the bar magnets 120a-120f. For instance, the coiled wire 111 may be positioned above the bar magnets 120a-120f. The coiled wire 111 and the bar magnets 120a-120f may be aligned to have similar or identical distances to the shaft 105. The coiled wire 111 can be coiled around a conductor wire 113 which is further connected to another component of the apparatus 100 or an external component. Therefore, the electrical current generated can be utilized to supply power to another component of the apparatus 100 and/or stored in a battery 115 that may be part of the apparatus 100 or an external component.

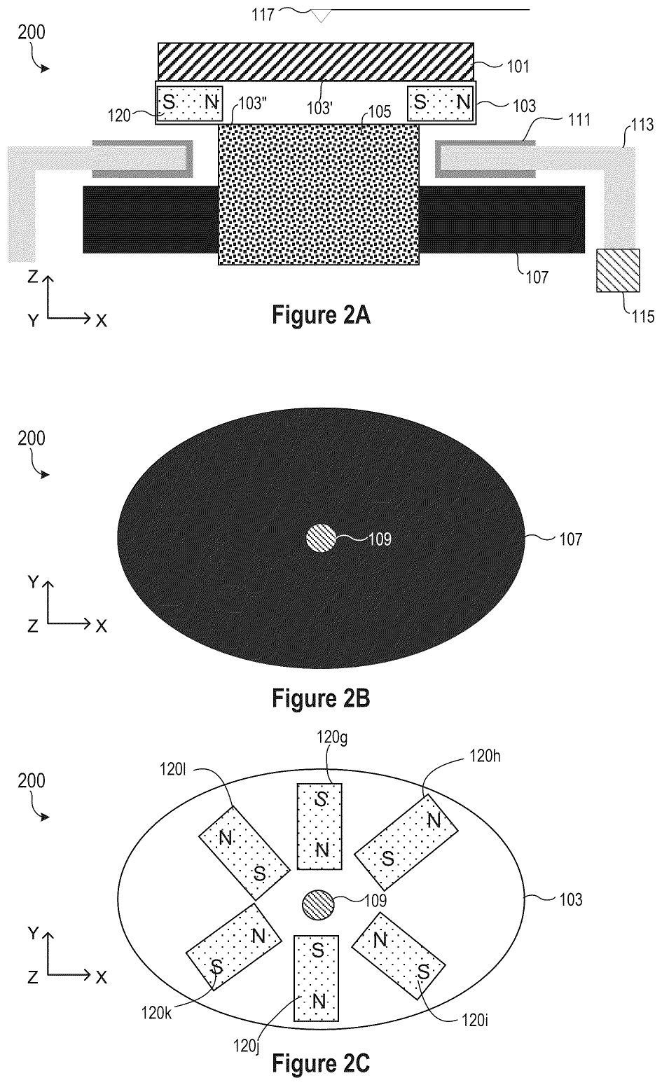

FIG. 2A shows a vertical cross-sectional view of a substrate processing apparatus (hereinafter referred to as an apparatus 200), and FIGS. 2B and 2C show horizontal cross-sectional views of the plate 107 and the substrate holder 103 respectively in accordance with some embodiments of the present disclosure. The embodiment of the apparatus 200 is similar to the embodiment of the apparatus 100. Note that similar or identical components are labeled with similar or identical numerals unless specified otherwise. Descriptions have been provided above and will be omitted for simplicity purposes.

As shown, the apparatus 200 includes the magnets 120 such as bar magnets 120g, 120h, 120i, 120j, 230k and 120l. The bar magnets 120g-120l are integrated with the substrate holder 103 so that the bar magnets 120g-120l are part of the substrate holder 103. For instance, the bar magnets 120g-120l can be embedded in the substrate holder 103. As a result, the bar magnets 120g-120l are configured to rotate with the substrate holder 103 when the shaft 105 rotates. The position of the bar magnets 120g-120l in the vertical direction (i.e. the Z direction) is not particularly limited. Preferably, the bar magnets 120g-120l are closer to a bottom surface 103′ of the substrate holder 103 than a top surface 103′ of the substrate holder 103. The bar magnets 120g-120l may preferably be covered by the bottom surface 103′ of the substrate holder 103 or alternatively be exposed.

In some embodiments, the bar magnets 120g-120l are arranged along the direction of the circumference of the shaft 105 (or the insert opening 109). Each of the bar magnets 120g-120l has a respective magnetic pole pointing towards the shaft 105 and another respective magnetic pole pointing away from the shaft 105. In other words, the bar magnets 120g-120l each have a respective longitudinal direction that passes or is aligned to point towards the shaft 105. Preferably, the bar magnets 120g-120l are distributed uniformly along the direction of the circumference of the shaft 105; that is, the bar magnets 120g-120l may each form a 60-degree angle with a neighboring bar magnet. Alternatively, the bar magnets 120g-120l may be distributed non-uniformly along the direction of the circumference of the shaft 105.

The bar magnets 120g-120l can have alternating or reversed magnetic polarity along the direction of the circumference of the shaft 105. Consider the bar magnet 120i for example. The bar magnet 120i has a magnetic north pole pointing towards the shaft 105 while neighboring bar magnets (120h and 120j) each have a respective magnetic south pole pointing towards the shaft 105 in the example of FIG. 1B. In an alternative example, the bar magnet 120i can have a magnetic south pole pointing towards the shaft 105 while neighboring bar magnets (120h and 120j) each have a respective magnetic north pole pointing towards the shaft 105. Accordingly, the apparatus 100 may preferably include an even number (e.g. two, four, six, eight, etc.) of bar magnets.

The coiled wire 111 can be positioned adjacent to the substrate holder 103 or adjacent to the bar magnets 120g-120l. For instance, the coiled wire 111 may be positioned below the bar magnets 120g-120l. The coiled wire 111 and the bar magnets 120g-120l may be aligned to have similar or identical distances to the shaft 105. Similarly, an electrical current is generated by the coiled wire 111 due to changing magnetic fields of the bar magnets 120g-120l that are rotating during operation.

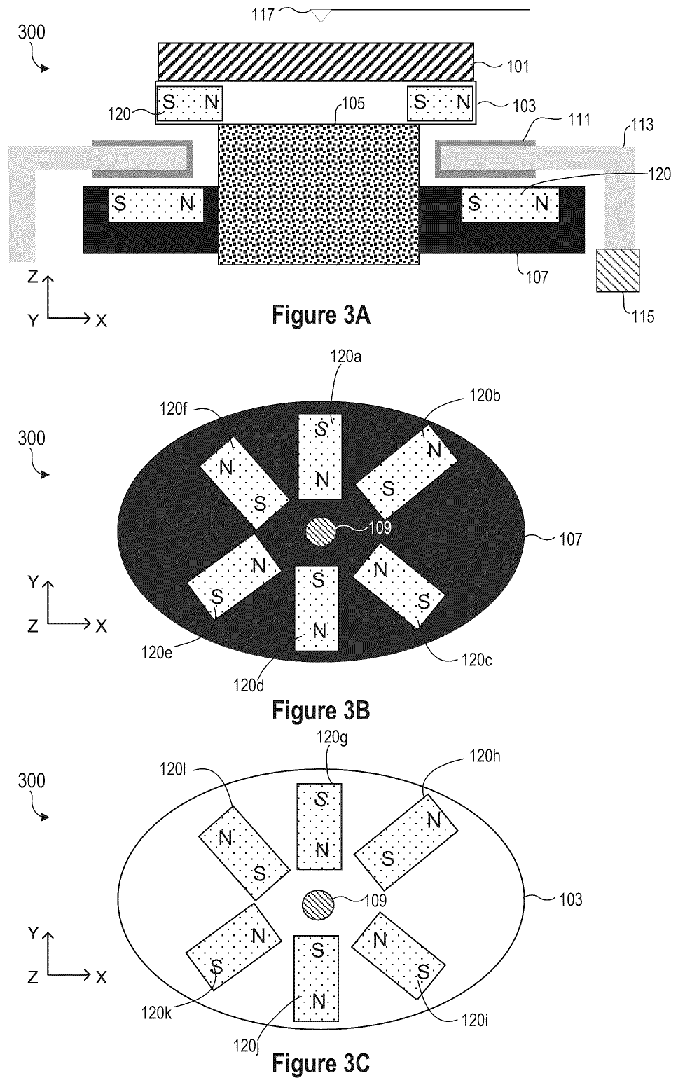

FIG. 3A shows a vertical cross-sectional view of a substrate processing apparatus (hereinafter referred to as an apparatus 300), and FIGS. 3B and 3C show horizontal cross-sectional views of the plate 107 and the substrate holder 103 respectively in accordance with some embodiments of the present disclosure. The embodiment of the apparatus 300 is similar to the embodiment of the apparatus 100. Note that similar or identical components are labeled with similar or identical numerals unless specified otherwise. Descriptions have been provided above and will be omitted for simplicity purposes.

As shown, the apparatus 300 includes the bar magnets 120a-120f integrated with the plate 107 as well as the bar magnets 120g-120l integrated with the substrate holder 103. Accordingly, the coiled wire 111 can be positioned adjacent to the plate 107 and the substrate holder 103 e.g. between the plate 107 and the substrate holder 103. As a result, an electrical current is generated by the coiled wire 111 due to changing magnetic fields of the bar magnets 120a-120l that are rotating during operation. While shown to have magnetic polarity aligned in the example of FIG. 3A, the bar magnets 120a-120l may have their magnetic polarity staggered or misaligned.

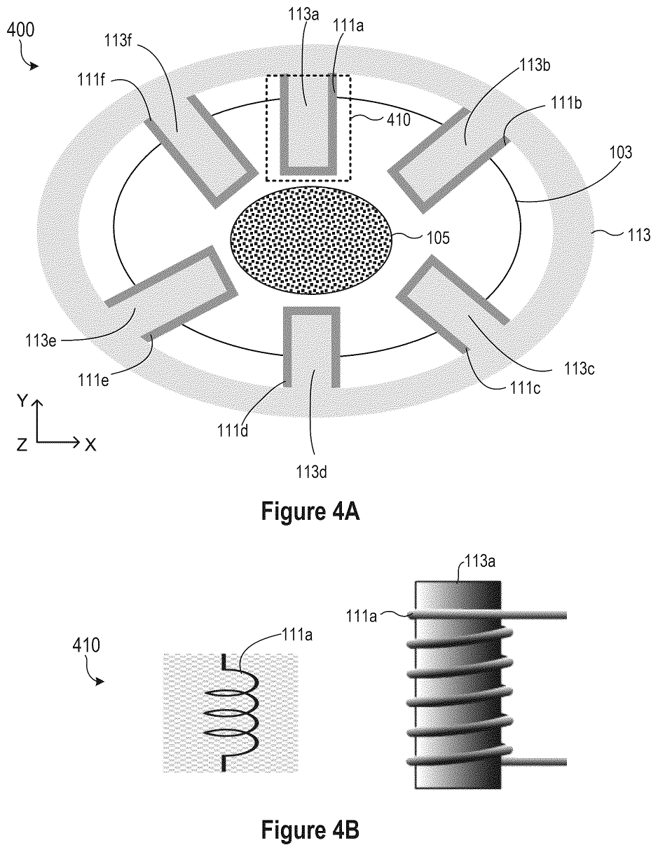

FIG. 4A shows a horizontal cross-sectional view of the conductor wire 113 and the substrate holder 103 of the apparatus 100, 200, 300 or the like, and FIG. 4B shows an expanded local view of Box 410, in accordance with some embodiments of the present disclosure. A plurality of coiled wires 111a, 111b, 111c, 111d, 111e and 111f can be arranged along the direction of the circumference of the shaft 105. Each of the coiled wires 111a, 111b, 111c, 111d, 111e and 111f can be coiled around a respective plunger structure 113a, 113b, 113c, 113d, 113e and 113f that are part of the conductor wire 113.

The number of the coiled wires is not particularly limited. For instance, the conductor wire 113 can include an odd or even number of coiled wires coiled around respective plunger structures. While the number of coiled wires are shown to be equal to the number of bar magnets integrated with the substrate holder 103 and/or the number of bar magnets integrated with the plate 107, it should be understood that the number of coiled wires (e.g. 111a), the number of bar magnets (e.g. 120g) integrated with the substrate holder 103, and the number of bar magnets (e.g. 120a) integrated with the plate 107 are independent of each other and thus may be the same or different, depending on specific design needs. Additionally, while shown to have a single coiled wire (e.g. 111a) coiled around each plunger structure (e.g. 113a), a plurality of or any number of coiled wires can be coiled around each plunger structure.

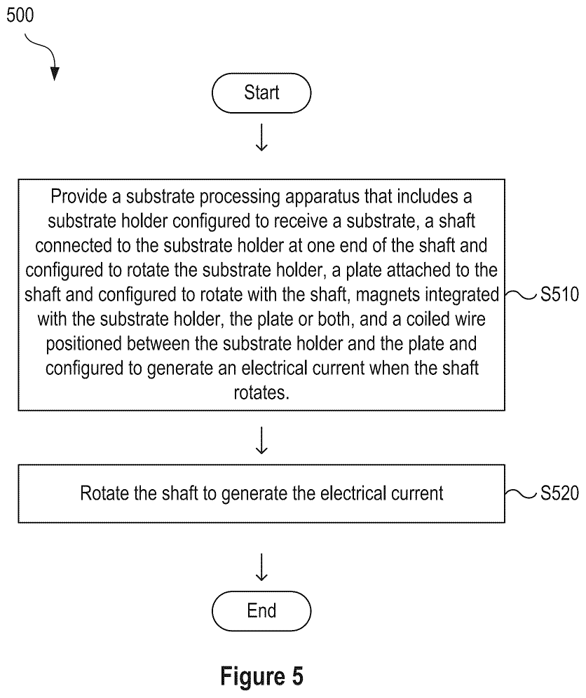

FIG. 5 shows a flow chart of a process 500 of energy generation, in accordance with some embodiments of the present disclosure. As step S510, a substrate processing apparatus is provided by a user oneself or another party. The substrate processing apparatus includes a substrate holder configured to receive a substrate, a shaft connected to the substrate holder at one end of the shaft and configured to rotate the substrate holder, a plate attached to the shaft and configured to rotate with the shaft, magnets integrated with the substrate holder, the plate or both, and a coiled wire positioned between the substrate holder and the plate and configured to generate an electrical current when the shaft rotates. At step S520, the shaft is rotated to generate the electrical current.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A substrate processing apparatus, comprising:
a substrate holder configured to receive a substrate;
a shaft connected to the substrate holder at one end of the shaft and configured to rotate the substrate holder;
a plate attached to the shaft and configured to rotate with the shaft;
magnets integrated with the substrate holder, the plate or both; and
a coiled wire positioned between the substrate holder and the plate and configured to generate an electrical current when the shaft rotates.

2. The substrate processing apparatus of claim 1, wherein:
the magnets include bar magnets arranged along a direction of a circumference of the shaft.

3. The substrate processing apparatus of claim 2, wherein:
the bar magnets each have a respective magnetic pole pointing towards the shaft.

4. The substrate processing apparatus of claim 3, wherein:
the bar magnets have alternating magnetic polarity along the direction of the circumference of the shaft.

5. The substrate processing apparatus of claim 4, wherein:
the magnets include an even number of the bar magnets.

6. The substrate processing apparatus of claim 2, wherein:
the bar magnets are configured to rotate around the shaft when the shaft rotates.

7. The substrate processing apparatus of claim 1, wherein:
the magnets are embedded in the plate.

8. The substrate processing apparatus of claim 1, wherein:
the magnets are embedded in the substrate holder.

9. The substrate processing apparatus of claim 1, wherein:
the magnets are embedded in the plate and the substrate holder.

10. The substrate processing apparatus of claim 1, wherein:
the coiled wire is configured to be stationary when the shaft rotates.

11. The substrate processing apparatus of claim 1, further comprising:
a conductor wire around which the coiled wire coils.

12. The substrate processing apparatus of claim 11, further comprising:
a battery connected to the conductor wire and configured to receive and store the electrical current.

13. The substrate processing apparatus of claim 1, wherein:
the shaft extends through the plate,
the plate is below the coiled wire, and
the coiled wire is below the substrate holder.

14. The substrate processing apparatus of claim 1, wherein:
the substrate processing apparatus comprises a plurality of coiled wires arranged along a direction of a circumference of the shaft.

15. The substrate processing apparatus of claim 1, further comprising:
a nozzle configured to discharge a liquid onto the substrate.

16. A method of energy generation, the method comprising:
providing a substrate processing apparatus that comprises:
a substrate holder configured to receive a substrate,
a shaft connected to the substrate holder at one end of the shaft and configured to rotate the substrate holder,
a plate attached to the shaft and configured to rotate with the shaft,
magnets integrated with the substrate holder, the plate or both, and
a coiled wire positioned between the substrate holder and the plate and configured to generate an electrical current when the shaft rotates; and
rotating the shaft to generate the electrical current.

17. The method of claim 16, further comprising:
transferring the electrical current to a battery via a conductor wire around which the coiled wire coils.

18. The method of claim 16, further comprising:
keeping the coiled wire stationary when rotating the shaft.

19. The method of claim 16, wherein:
the substrate processing apparatus comprises a spin coater.

20. The method of claim 19, further comprising:
forming a thin film on the substrate by spin coating.
